(19) United States
(12) Patent Application Publication
(10) Pub. No.: US 2026/0101633 A1
(43) Pub. Date: Apr. 9, 2026

(54) ORGANIC ELECTROLUMINESCENT DEVICES

(71) Applicant: Universal Display Corporation, Ewing, NJ (US)

(72) Inventors: Haridas Mundoor, Ewing, NJ (US); Nicholas J. Thompson, New Hope, PA (US)

(21) Appl. No.: 19/348,670

(22) Filed: Oct. 2, 2025

Related U.S. Application Data
(60) Provisional application No. 63/703,477, filed on Oct. 4, 2024.

(51) Int. Cl. H10K 50/85; H10K 102/00

(52) U.S. Cl. CPC H10K 50/85; H10K 2102/331

(57) ABSTRACT

Organic electroluminescent devices are provided, including devices having an outcoupling layer with shaped structures. The shaped structures can induce strong field confinement in the outcoupling layer to enhance the Purcell values at different wavelengths. The shape and/or dimensions of the shaped structures can be selected to tune the devices for particular wavelengths.

### FIELD

The present invention relates to emissive devices including organic emissive devices with a plurality of sub-pixels that may be stacked in the same device, and techniques for fabricating the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent molecules capable of phosphorescent emission is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 580-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-500 nm; a “yellow” layer, material, region, or device refers to one that has an emission spectrum with a peak wavelength in the range of about 540-600 nm; a “cyan” layer, material, or device refers to one that emits or has an emission spectrum with a peak wavelength in the range of about 490-520 nm; and an “orange” layer, material, or device refers to one that emits or has an emission spectrum with a peak wavelength in the range of about 570-620 nm. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-500 nm, and a “deep blue” or “dark blue” component has a peak emission wavelength in the range of about 400-470 nm, though these ranges may vary for some configurations. A “light green” component has a peak emission wavelength in the range of about 520-560 nm, and a “deep green” or “dark green” component has a peak emission wavelength in the range of about 500-520 nm, though these ranges may vary for some configurations. Similarly, a color altering layer refers to a layer that converts or modifies another color of light to light having a wavelength as specified for that color. For example, a “red” color filter refers to a filter that results in light having a wavelength in the range of about 580-700 nm. In some arrangements, separate regions, layers, materials, regions, or devices may provide separate “near infrared (NIR)” and a “short wave infra-red (SWIR)” light. Typically, a “NIR” component has a peak emissions wavelength in the range of about 700-1400 nm, and a “SWIR” component has a peak emission wavelength in the range of about 1400-3000 nm, though these ranges may vary for some configurations. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon the spectrum of light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373 I, 0.6245]; [0.6270, 0.3725]; |
| | Interior: [0.3 700, 0.4087]; [0.2886, 0.4572] |

More details on OLEDs, and the definitions described above, can be found in U.S. Pat. No. 7,279,704, which is incorporated herein by reference in its entirety.

### SUMMARY

According to an embodiment, an organic light emitting diode/device (OLED) is also provided. The OLED can include an anode, a cathode, and an organic layer, disposed between the anode and cathode. According to an embodiment, the organic light emitting device is incorporated into one or more devices selected from a consumer product, an electronic component module, and/or a lighting panel.

An organic emissive device is provided which includes a substrate; a first electrode; an emissive layer disposed over the first electrode; an enhancement layer disposed over the emissive layer; and an outcoupling layer disposed over the enhancement layer, wherein the outcoupling layer comprises a plurality of shaped structures, wherein each of the shaped structures comprises nanoparticles. The nanoparticles may be located in an interior of the shaped structure. The shape of the shaped structures may be selected to enhance a Purcell factor of the device. The bottom edge of the nanoparticles may be located on a plane different than a bottom edge of the shaped structures. The bottom edge of the nanoparticles may be located on the same plane as the bottom edge of the shaped structures. In other words, the plane of the bottom of the nanoparticles may be above and/or below the plane of the shaped structures or on the same plane as the shaped structures.

The emissive may include a phosphorescent emitter, a phosphor-sensitized fluorescent emitter, a thermally-activated delayed fluorescence (TADF) emitter, a phosphor-sensitized TADF, and/or a fluorescent emitter. The enhancement layer may be a second electrode within the organic emissive device. Alternatively, the device may include a second electrode in addition to the enhancement layer. In an embodiment, the second electrode that is separate from the enhancement layer may be disposed between the emissive layer and the enhancement layer or may be disposed above the enhancement layer. When the second electrode is between the emissive layer and the enhancement layer, the enhancement layer may be disposed directly on top of the second electrode.

The second electrode may be an optically transparent material or a metal material and selection thereof may be based upon the location of the second electrode within the OLED stack. The second electrode may have a thickness of less than 60 nm. A distance between the second electrode and the emissive layer and/or enhancement layer may be less than 30 nm.

The nanoparticles may be in direct contact with the enhancement layer. The device may also include a dielectric layer disposed between the enhancement layer and the outcoupling layer. The outcoupling layer may alternatively, or additionally, include a dielectric layer that is disposed outside the shaped structures and within the shaped structures of the outcoupling layer. The nanoparticles may be disposed in direct contact with a top of the dielectric layer of the outcoupling layer within the shaped structures. The nanoparticles may be distributed within the shaped structures in a periodic order, a random order, and/or in a quasiperiodic order having substantially equal spacing without long-range positional ordering. The center-to-center spacing of the nanoparticles distributed within a shaped structure in a periodic order may be less than 2000 nm, less than 1500 nm, less than 1000 nm, less than 900 nm, less than 800 nm, less than 600 nm, or less than 500 nm. The nanoparticles may have a shape that may include cubes, hemispheres, cylinders, square pyramids, rectangular pyramids, triangular pyramids, and cuboids. The nanoparticles may include dielectric nanoparticles, where the dielectric material of the nanoparticles may have a refractive index of at least 1.8 or greater than 2.5. The nanoparticles may be metal nanoparticles that may include a plasmonic material.

The shaped structures of the outcoupling layer may be made from a metal material and/or a dielectric material. The shaped structures may be distributed within the outcoupling layer in a periodic positional order or a random positional order. The device may include dielectric shaped structures and dielectric nanoparticles, dielectric shaped structures and metal nanoparticles, metal shaped structures and dielectric nanoparticles, or metal shaped structures and metal nanoparticles. Each of the shaped structures may include a single nanoparticle. The shaped structures may be a of a ring shape. The walls of the ring shape may include a wavy pattern. The wavy pattern may have a thickness, a width, and an amplitude. The amplitude may be a difference between a shortest inner edge-to-edge spacing and a longest inner edge-to-edge spacing. The amplitude may be less than 50 nm, less than 100 nm, or less than 200 nm.

The Purcell factor may be enhanced for a predetermined wavelength based upon a selection of a predetermined value for at least one dimension of the shaped structure. A selected inner diameter of the shape may enhance the Purcell factor for a range of wavelength values. The inner diameter of the ring shape may be less than 550 nm. To enhance the Purcell factor for a range of wavelength values corresponding to red optical emissions, the inner diameter may be 500 nm±50 nm. To enhance the Purcell factor for a range of wavelength values corresponding to green optical emissions, the inner diameter may be 420 nm±50 nm. To enhance the Purcell factor for a range of wavelength values corresponding to blue optical emissions, the inner diameter may be 350 nm±50 nm. A width of the shaped structure, for example, the ring shape or the wavy pattern shape, may change an intensity of an optical emission. The width of the shaped structures, which may be a difference between an outer radius and an inner radius of the shaped structure, may be less than 200 nm or may be 100 nm±10 nm. An inner radius of the shaped structure, for example, the ring shape, may be less than 2 microns. A thickness of the shaped structure, which is an out-of-plane dimension of the shaped structure, may be less 100 nm or may be 50 nm±5 nm. The outer radius of the shaped structure may be greater than 300 nm and less than 3000 nm.

The device may be or may be a part of a consumer electronic device, which may be at least one type selected from the group consisting of: a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, an automotive display, a video walls comprising multiple displays tiled together, a theater or stadium screen, and a sign.

### BRIEF DESCRIPTION OF THE DRAWINGS

FIG. 1 shows an organic light emitting device.

FIG. 2 shows an inverted organic light emitting device that does not have a separate electron transport layer.

FIG. 3A-3H show a schematic representation of plasmonic OLEDs utilizing ring shaped structures in the outcoupling layer. FIG. 3A shows a ring enclosing an array of metal particles. FIG. 3B illustrates the dimensions of the ring structures. FIG. 3C and FIG. 3D show a ring enclosing a single metal nanoparticle. FIG. 3E shows a ring enclosing an array of dielectric nanoparticles. FIGS. 3F, 3G, and 3H show a ring enclosing a single dielectric nanoparticle. FIG. 3D, 3G, 3H represent the plasmonic OLED design where the enhancement layer is not an electrode. In FIG. 3D and FIG. 3G the enhancement layer is deposited directly on the electrode. FIG. 3H represents the plasmonic OLED design including a dielectric layer between the enhancement layer and electrode.

FIG. 4A-4C show a schematic representation of plasmonic OLEDs utilizing a wavy pattern around nanoparticles. FIG. 4A shows the wavy pattern around an array of metal particles.

FIG. 4B shows the wavy pattern around a single metal nanoparticle. FIG. 4C shows a schematic of dimensions of the wavy ring structure.

FIG. 5 shows a simulated Purcell enhancement for a plasmonic OLED without an outcoupling layer (dashed line) and a device using a single dielectric nanoparticle enclosed within a metallic ring for light outcoupling (solid line), showing Purcell enhancement at 550 nm induced by the outcoupling structures.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

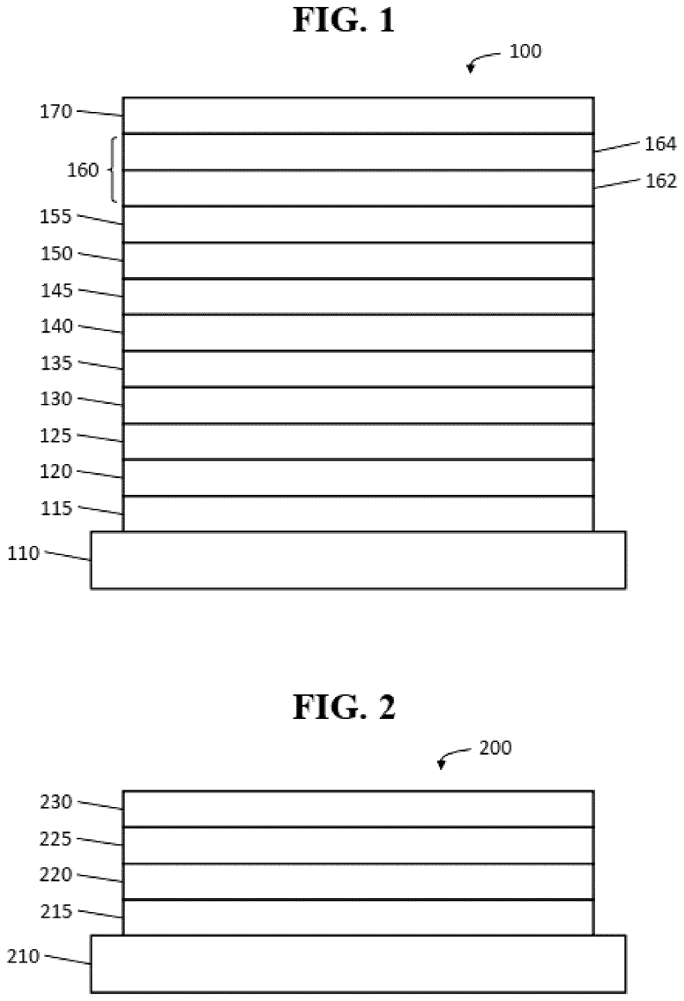

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. Barrier layer 170 may be a single- or multi-layer barrier and may cover or surround the other layers of the device. The barrier layer 170 may also surround the substrate 110, and/or it may be arranged between the substrate and the other layers of the device. The barrier also may be referred to as an encapsulant, encapsulation layer, protective layer, or permeation barrier, and typically provides protection against permeation by moisture, ambient air, and other similar materials through to the other layers of the device. Examples of barrier layer materials and structures are provided in U.S. Pat. Nos. 6,537,688, 6,597,111, 6,664,137, 6,835,950, 6,888,305, 6,888,307, 6,897,474, 7,187,119, and 7,683,534, each of which is incorporated by reference in its entirety.

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIGS. 1-2, respectively, may include quantum dots. The emissive layer may use different emissive display technologies. Such technologies may include inorganic and/or organic devices, such as LEDs, mini LEDs, microLEDs, thin electroluminescent films, organic light emitting devices, and the like. An “emissive layer” or “emissive material” as disclosed herein may include an organic emissive material and/or an emissive material that contains quantum dots or equivalent structures, unless indicated to the contrary explicitly or by context according to the understanding of one of skill in the art. In general, an emissive layer includes emissive material within a host matrix. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light based on an injected electrical charge, where the initial light may be altered by another layer such as a color filter or other color altering layer that does not itself emit an initial light within the device, but may re-emit altered light of a different spectra content based upon absorption of the initial light emitted by the emissive layer and downconversion to a lower energy light emission. In some embodiments disclosed herein, the color altering layer, color filter, upconversion, and/or downconversion layer may be disposed outside of an OLED device, such as above or below an electrode of the OLED device.

Unless otherwise specified, any of the layers of the various embodiments may be placed, disposed, or deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, where the emitter material has a total non-radiative decay rate constant and a total radiative decay rate constant due to the presence of the enhancement layer and the threshold distance is where the total non-radiative decay rate constant is equal to the total radiative decay rate constant. In an embodiment, the plasmonic OLED may include an organic emissive layer having an organic emissive material disposed over the electrode, where the organic emissive material has a total non-radiative decay rate constant

$${k}_{non - rad}^{0} ,$$

a total radiative decay rate constant

$${k}_{rad}^{0} ,$$

a total non-radiative decay rate constant due to the enhancement layer

$${k}_{non - rad}^{p l a s m o n} ,$$

and a total radiative decay rate constant due to the enhancement layer

$${k}_{r a d}^{p l a s m o n} .$$

The plasmonic OLED may include an enhancement layer (either as a separate layer or as one of the electrodes) having a plasmonic material exhibiting surface plasmon resonance that non-radiatively couples to the organic emissive material and transfer excited state energy from the emissive material to non-radiative mode of surface plasmon polaritons, disposed over the organic emissive layer opposite from the first electrode. The enhancement layer may be provided no more than a threshold distance away from the organic emissive layer, where the threshold distance is a distance at which

$$\frac{{k}_{rad}^{plasmon}}{{k}_{non - rad}^{plasmon}} = \frac{{k}_{rad}^{0}}{{k}_{non - rad}^{0}} .$$

In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters or extracts the energy from the surface plasmon polaritons. In some embodiments this energy is scattered or extracted as photons to free space. In other embodiments, the energy is scattered or extracted from the surface plasmon mode into other modes of the device such as but not limited to the organic waveguide mode, the substrate mode, or another waveguiding mode. If energy is scattered or extracted to the non-free space mode of the OLED other outcoupling schemes could be incorporated to extract that energy to free space. In some embodiments, one or more dielectric layers can be disposed between the enhancement layer and the outcoupling layer. The examples for dielectric layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles where the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

In embodiments of the disclosed subject matter, a device may include an enhancement layer that is disposed over an emissive area of at least one sub-pixel that is configured to have a Lambertian emission and/or at least one sub-pixel having a microcavity configured for direct emission, as described in detail below. In at least some of such embodiments, the enhancement layer may include a plasmonic structure that is disposed a predetermined threshold distance from the emissive area. The predetermined threshold distance may be a distance at which a total non-radiative decay rate constant is equal to a total radiative decay rate constant. In some of such embodiments, device may include an outcoupling layer is disposed over the enhancement layer on the opposite side of the emissive area.

It is believed that the internal quantum efficiency (IQE) of fluorescent OLEDs can exceed the 25% spin statistics limit through delayed fluorescence. As used herein, there are two types of delayed fluorescence, i.e., P-type delayed fluorescence and E-type delayed fluorescence. P-type delayed fluorescence is generated from triplet-triplet annihilation (TTA).

In some embodiments, a compound in an emissive material and/or layer in an OLED may be used as a phosphorescent sensitizer, where one or multiple layers in the OLED may include an acceptor in the form of one or more fluorescent and/or delayed fluorescence emitters. In some embodiments, the compound can be used as one component of an exciplex to be used as a sensitizer. As a phosphorescent sensitizer, the compound may be capable of energy transfer to the acceptor, and the acceptor may emit the energy or further transfer energy to a final emitter. The acceptor concentrations may range from 0.001% to 100%. The acceptor may be in either the same layer as the phosphorescent sensitizer or in one or more different layers. In some embodiments, the acceptor may be a TADF emitter. In some embodiments, the acceptor may be a fluorescent emitter. In some embodiments, the emission may arise from any or all of the sensitizer, acceptor, and/or final emitter.

On the other hand, E-type delayed fluorescence described above does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small AES-T. These states may involve CT states. Often, donor-acceptor luminescent materials are constructed by connecting an electron donor moiety such as amino- or carbazole-derivatives and an electron acceptor moiety such as N-containing six-membered aromatic ring.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, an automotive display, a video walls comprising multiple displays tiled together, a theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer having carbon nanotubes.

In some embodiments, the OLED further comprises a layer having a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host.

In some embodiments, the compound causing light to be generated can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes, including phosphor sensitized fluorescence.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

The Purcell effect is the enhancement of a device's spontaneous emission rate caused by its environment. In a plasmonic OLED, the Purcell enhancement enabled by the coupling of electrically generated excitons to the surface plasmon modes of the enhancement layer increases the device stability. In many plasmonic OLEDs using nanoparticles for light outcoupling, the device stability enhancement depends on the separation between the emissive layer (EML) and the enhancement layer. The nanoparticles in the outcoupling layer contribute minimally to the device stability. In an embodiment, the outcoupling layer includes outcoupling designs for plasmonic OLEDs which can induce strong field confinement in the outcoupling layer to enhance the Purcell factor and achieve significant enhancement in device stability while simultaneously scattering or extracting photons from the enhancement layer, leading to enhancing the device external quantum efficiency (EQE).

In plasmonic OLEDs, the coupling of emission to the surface plasmon modes of the enhancement layer leads to significant reduction in excited state lifetime of the emitter, which results in enhanced device stability by reducing the destabilizing excited state interactions. The reduction in excited state lifetime is characterized by the Purcell factor, defined as the ratio of radiative decay rates of the emitter in the device to that in vacuum. The stability enhancement for a plasmonic OLED with a given emissive layer (EML) thickness depends on the distance between the EML and the enhancement layer. In typical plasmonic OLEDs, the outcoupling layer contributes minimally to the overall Purcell enhancement. However, structures with strong field confined in the outcoupling layer can induce strong Purcell enhancement, which then enables increased device stability.

In an embodiment, the described device includes a substrate, an OLED 310 including a first electrode, an emissive layer 320 disposed over the first electrode, an enhancement layer 330 disposed over the emissive layer, and an outcoupling layer 340 disposed over the enhancement layer. Here, OLED 310 may include different variations of layers, for example, additional layers, the layers in a different order, and/or the like including, but not limited to, transport layers (e.g., HIL, HTL, EBL, HBL, ETL, EIL, etc.). Such stacks are described in connection with FIG. 1 and FIG. 2. The described device includes a unique outcoupling layer 340 that includes shaped structures. The shaped structures surround nanoparticles of the outcoupling layer. In an embodiment, the shaped structure may be any shape or structure that allows for the placement of nanoparticles inside the structure. In other words, an interior portion of the shaped structure allows for the placement of one or more nanoparticles. The bottom edge of the nanoparticles may be located on the same or a different plane as the bottom edge of the shaped structures. In other words, the plane of the bottom of the nanoparticles may be above and/or below the plane of the shaped structures or on the same plane as the shaped structures. Additionally, the bottom edge of each of the nanoparticles may be located in a different plane as compared to the bottom edge of others of the nanoparticles. Thus, the bottom edge of some nanoparticles may be in a plane above the bottom edge of some shaped structures, may be in a plane below the bottom edge of some shaped structures, may be on the same plane as the bottom edge of the shaped structures, and/or the like, or a combination thereof. Alternatively, the bottom edge of all the nanoparticles may be within the same plane. In yet another embodiment, the top of the nanoparticles may be on the same plane as the top of the shaped structure. Alternatively, the top of the nanoparticles may be in a plane above or below the top of the shaped structure. In some embodiments, the shaped structures enhance the Purcell factor, by inducing strong field confinement in the outcoupling layer. The shaped structures are used to confine the surface plasmons to achieve Purcell values higher than plasmonic OLEDs without an outcoupling layer, thereby increasing the device stability and lifetime, while the nanoparticles (NPs) within the shaped structures converts the plasmons within the enhancement layer to photons that are emitted or scattered or extracted to free space for high efficiency. Thus, the shape of the shaped structures is selected to enhance the Purcell factor of the device.

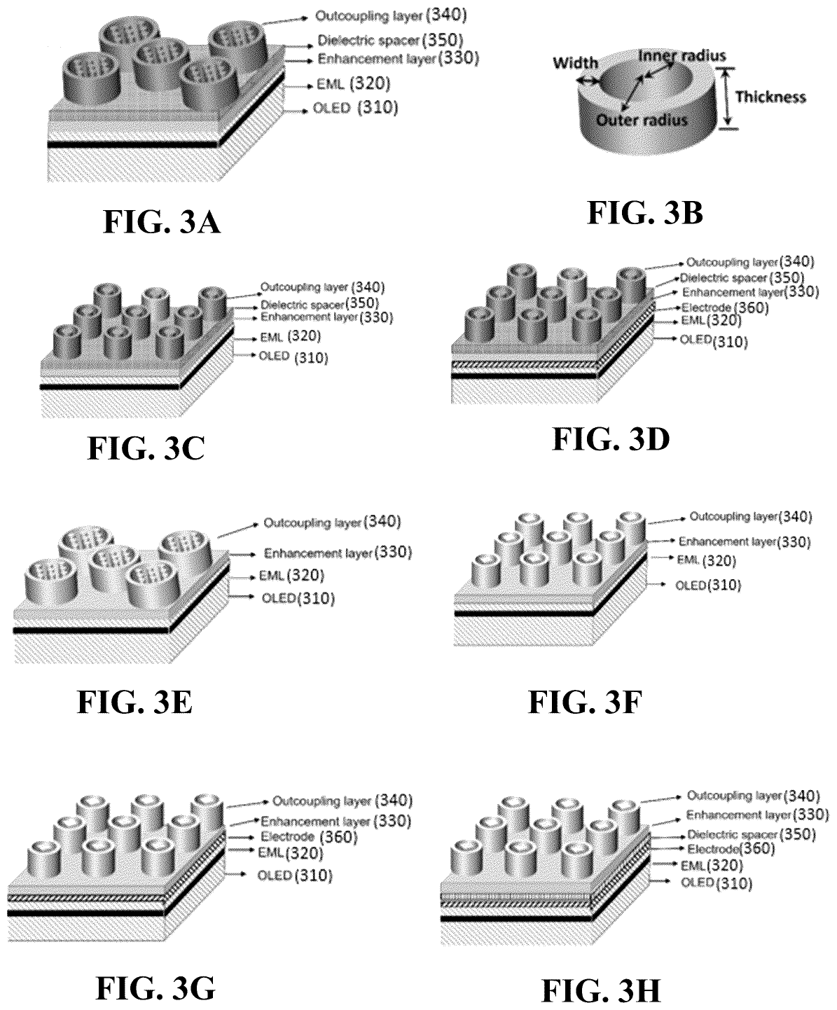

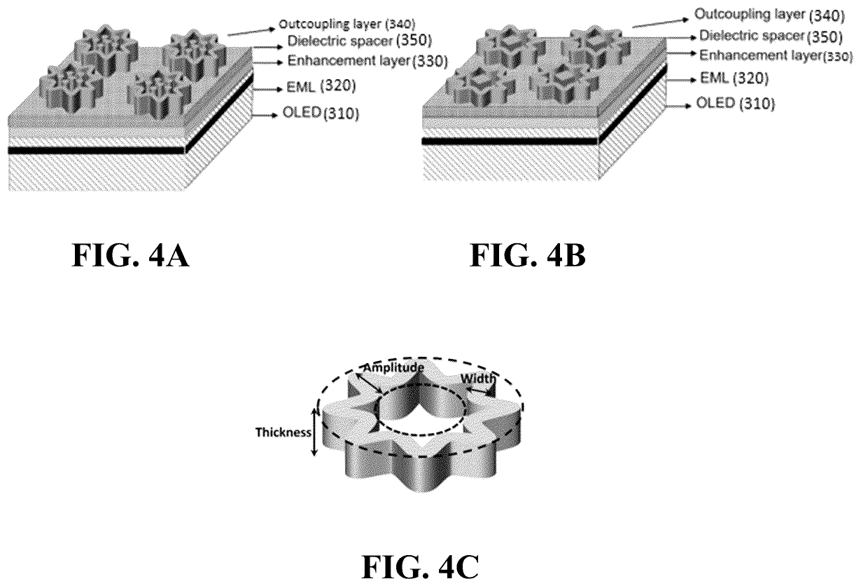

The shape of the shaped structures is selected to confine the surface plasmons. Accordingly, the shape may be a ring shape, as illustrated and discussed in connection with FIG. 3a-FIG. 3h. However, the walls of the ring shape do not need to be straight sided. Rather, to increase the wavelength range of the Purcell enhancement, the walls of the ring shape may be a wavy pattern, for example, as illustrated and discussed in connection with FIG. 4a-FIG. 4c. Other shapes can be utilized, for example, square shapes, rectangular shapes, oval shapes, star shapes, and/or the like. Shapes with corners may cause the accumulation of the surface plasmons in the corners, which may decrease the efficiency and/or confinement of the outcoupling structure but may increase the field strength. In an embodiment, the walls shaped structure may extend from the dielectric spacer 350, if the dielectric spacer 350 is found within the device, or the enhancement layer 330 at 90 degrees from the plane of the dielectric spacer 350 and/or enhancement layer 330. In alternative embodiments, the interior walls of the shaped structure may extend from the dielectric spacer 350, if found within the device, or the enhancement layer 330 at 70-110 degrees from the plane of the dielectric spacer 350 and/or enhancement layer 330. In alternative embodiments, the exterior walls of the shaped structure may extend from the dielectric spacer 350, if found within the device, or the enhancement layer 330 at 70-110 degrees from the plane of the dielectric spacer 350 and/or enhancement layer 330. In an embodiment, the slope of the interior walls of the shaped structure may be the same as the slope of the exterior wall of the shaped structure. In an alternative embodiment, the slope of the interior walls of the shaped structure may be different from the slope of the exterior wall of the shaped structure

FIG. 3a-FIG. 3h show schematics of plasmonic OLEDs utilizing different outcoupling schemes and different stack layers. In some embodiments, the enhancement layer 330 is a metallic layer that is deposited on the top surface of the organic layers. In this case, the enhancement layer may act as an electrode, for example, the cathode. In an alternative embodiment, the enhancement layer 330 may be deposited on top of the electrode. The thickness of the enhancement layer may be 10-60 nm, or most preferably 10-40 nm. As illustrated, the outcoupling layer 340 includes many units of shaped structures (ring-shaped structures in the examples of FIG. 3a-FIG. 3h), with nanoparticles arranged within the shaped structures. In one embodiment, the number of nanoparticles within the shaped structures is a single nanoparticle, as illustrated in FIG. 3c, FIG. 3d, FIG. 3f, FIG. 3g, and FIG. 3h. In an alternative embodiment, any number of nanoparticles may be located within the shaped structures. For example, each shaped structures may include two nanoparticles, three nanoparticles, etc. In an alternative example, a first shaped structure may include two nanoparticles and a second shaped nanoparticle may include three nanoparticles, etc. Alternatively, or additionally, the nanoparticles within the shaped structures may form an array, as illustrated in FIG. 3a and FIG. 3e. The shaped structures with the nanoparticles may be arranged having a random positional order or may be arranged in arrays having a periodic, quasiperiodic, etc., order. The arrays may have a positional order and may be a combination of similar array patterns (e.g., a combination of two or more square arrays each having different spacing, a combination of two or more hex arrays each having different spacings, etc.), may be a combination of different array patterns, (e.g., a combination of a square array and a hex array having the same spacing as each other, a combination of a square array and a hex array having different spacing as compared to each other, etc.), Moire arrays, Penrose arrays, and/or the like. For shaped structures being arranged in a random positional order, the average edge-to-edge spacing between shaped structures may be 10 nm, 20 nm, 30 nm, 50 nm, 75 nm, 100 nm, 125 nm, 150 nm, 175 nm, and/or 200 nm. A minimum edge spacing may be 1 nm, 2 nm, 3 nm, 5 nm, 10 nm, 25 nm, 50 nm, 75 nm, and/or 100 nm.

The shaped structures, either the ring shape or a different shape, may be prepared using metals such as gold, silver, aluminum, palladium, platinum, ytterbium, iridium, nickel, copper, tungsten, tantalum, iron, chromium, gallium, rhodium, titanium, ruthenium, bismuth, calcium, or magnesium, alloys of these metals, combinations of these metals, and/or the like. Alternatively, or additionally, the shaped structures may be prepared using dielectric materials having a refractive index of at least 1.0, at least 1.4, at least 1.7, at least 1.8, at least 2.0, at least 2.2, at least 2.5, or, preferably, 2.4±0.1. Example dielectric materials may include, but are not limited to, silicon nitride, boron nitride, silicon carbide, carbon, diamond, zinc sulfide, zinc selenide, germanium, zinc telluride, potassium niobate, titanium oxide, titanium dioxide, antimony oxide, indium dioxide, silicon dioxide, niobium pentoxide, tantalum pentoxide, vanadium oxide, vanadium pentoxide, gallium phosphate, bismuth oxide, gallium arsenide, and/or aluminum gallium. The nanoparticles may also be prepared using metals such as gold, silver, aluminum, palladium, platinum, ytterbium, iridium, nickel, copper, tungsten, tantalum, iron, chromium, gallium, rhodium, titanium, ruthenium, bismuth, calcium, or magnesium, alloys of these metals, combinations of these metals, and/or the like. The shaped structures and nanoparticles may be prepared of the same or different metals. The size of the shaped structures and nanoparticles can be sized to achieve desired results. In other words, the size of the shaped structures and size of the nanoparticles can be tuned to achieve the desired results. When both the shaped structure and the nanoparticles are made of metallic materials, the Purcell enhancement and EQE can be higher when they are made of the same material as the enhancement layer.

Metal nanoparticles may also include a plasmonic material. Alternatively, or additionally, the nanoparticles may be prepared using dielectric materials having a refractive index of at least 1.0, at least 1.4, at least 1.7, at least 1.8, at least 2.0, at least 2.2, or, preferably, greater than 2.5. Thus, the combinations of shaped structures and nanoparticles include dielectric shaped structures and dielectric nanoparticles, dielectric shaped structures and metal nanoparticles, metal shaped structures and dielectric nanoparticles, and metal shaped structures and metal nanoparticles. The most commonly used combination may be dielectric shaped structures with metal nanoparticles. For embodiments having shaped structures and nanoparticles both being made of dielectric materials, higher index materials may be preferred. The nanoparticles may also be made of photonic crystals.

Dimensions of the shaped structures can be modified to tune the device for particular wavelengths. In other words, the field localization induced by the shaped structures enhances the Purcell factor values at specific wavelength ranges, which can be tuned by changing dimensions of the shaped structure. The dimensions of the ring-shaped structures are illustrated in FIG. 3b. Different materials used for the shaped structures may result in different dimensions for tuning. In the case of the ring-shaped structures with straight sides, the inner radius of the ring may be less than 300 nm, less than 500 nm, less than 1 micron, and/or less than 2 microns. The thickness of the ring, which is the out-of-plane dimension of the ring, may be less than 100 nm, less than 50 nm, less than 30 nm, or, preferably, 50 nm+5 nm. The width of the ring, which is defined as the difference between the outer radius and the inner radius of the ring, may be less than 50 nm+/−25 nm, 75 nm+/−25 nm, 100 nm+/−25 nm, 150+/−25 nm, 200 nm+/−25 nm, or above, or, preferably, 100 nm+10 nm. With an increase in the width of the shaped structures, the metallic losses may increase which can lead to a reduced outcoupling efficiency. The outer radius may be greater than 300 nm and less than 3000 nm.

To tune the device for a red emitter (or a red electroluminescent (EL) or optical emission) with a peak emission wavelength of approximately 620 nm, the inner diameter of the ring may be 500±25 nm. To tune for a green emitter (or a green electroluminescent (EL) or optical emission) with a peak emission wavelength of approximately 530 nm, the inner diameter of the ring may be 420±25 nm. To tune for a blue emitter (or a blue electroluminescent (EL) or optical emission) with a peak emission wavelength of approximately 480 nm, the inner diameter of the ring may be 350±25 nm. Thus, variations of the inner diameter generally control the emission spectrum range. Varying the width of the ring can control the intensity of the emission spectrum. Thus, while the dimensions of the shaped structure can tune the device for particular wavelengths, dimensions may also be utilized to tune the device for other characteristics.

To increase the wavelength range of Purcell enhancement, the ring structures may have, instead of straight sides, sides having a wavy pattern as illustrated in FIG. 4a-FIG. 4c. This is referred to as a shape having a wavy pattern. However, it should be noted that the overall shape is still a ring shape. It is just a ring shape having wavy sides. FIG. 4a illustrates a shape having a wavy pattern with an array of nanoparticles contained within each of the shaped structures. FIG. 4b illustrates a shape having a wavy pattern with a single nanoparticle contained within each of the shaped structures. In the examples of FIG. 4a and FIG. 4b, the OLED stack is illustrated the same therebetween. However, it should be noted that the OLED stack could have any number of layers, for example, those as illustrated in connection with FIG. 3a-FIG. 3h. FIG. 4c illustrates the dimensions of the shape having a wavy pattern. The dimensions may include a thickness, a width, and an amplitude, as illustrated in FIG. 4c. The amplitude may be the difference between a shortest inner edge-to-edge spacing and a longest inner edge-to-edge spacing. The amplitude may be less than 50 nm, less than 100 nm, or less than 200 nm.

It should be noted that the device may include shaped structures that are tuned for different wavelengths on the same device. In other words, the device may include multiple shaped structures with subsets of the shaped structures being tuned for a particular wavelength and other subsets of the shaped structures being tuned for different wavelengths. Thus, not all shaped structures have to be tuned for the same wavelength or have the same dimensions as other of the shaped structures. Additionally, not all shaped structures have to have the same number of nanoparticles contained there within.

The distribution of nanoparticles within the shaped structure may be random or periodic. The distribution of the nanoparticles within the shaped structures may be arranged having a random positional order or may be arranged in arrays having a periodic, quasiperiodic, etc., order. The arrays may have a positional order and may be a combination of similar array patterns (e.g., a combination of two or more square arrays each having different spacing, a combination of two or more hex arrays each having different spacings, etc.), may be a combination of different array patterns, (e.g., a combination of a square array and a hex array having the same spacing as each other, a combination of a square array and a hex array having different spacing as compared to each other, etc.), Moire arrays, Penrose arrays, and/or the like. The shaped structures and the nanoparticles may have the same arrangement (e.g., random, array, etc.) as each other, or may have different arrangements as compared to each other. Additionally, in the case that both the shaped structures and the nanoparticles are arranged in an array, the arrays may be the same or different between the shaped structures and the nanoparticles. For example, the shaped structures and nanoparticles may both be arranged in square arrays (having the same or different spacing), may both be arranged in hexagonal arrays (having the same or different spacing), may be arranged so that the shaped structures are within a square array and the nanoparticles are within a quasiperiodic array, may be arranged so that the shaped structures are within a hexagonal array and the nanoparticles are within a square array, and/or the like. Additionally, the shaped structures may be arranged in a combination of arrays and the nanoparticles may be arranged in a combination of arrays. For example, the shaped structures may be arranged in a square array and a hexagonal array and the nanoparticles may be arranged in a square array and a quasiperiodic array. For nanoparticles being arranged in a random positional order, the average edge-to-edge spacing between shaped structures may be 10 nm, 20 nm, 30 nm, 50 nm, 75 nm, and/or 100 nm. A minimum edge spacing may be 1 nm, 2 nm, 3 nm, 5 nm, 10 nm, 25 nm, and/or 50 nm.

A periodic distribution is illustrated in FIG. 3a and FIG. 3e. The center-to-center spacing of the nanoparticles distributed within the shaped structure is less than 600 nm, less than 400 nm, and/or less than 300 nm. In some embodiments, the distribution of the nanoparticles within the shaped structure may be quasiperiodic, meaning the nanoparticles are located at almost equal spacing without any long-range positional ordering. For plasmonic OLED outcoupling structures, the length scale of the short-range positional order is often comparable to or less than the plasmon propagation length of the enhancement layer. The nanoparticles may be any three-dimensional shape including, but not limited to, cubes, hemispheres, cylinders, square pyramids, rectangular pyramids, triangular pyramids, cuboids, and/or any random irregular shaped particles.

When utilizing dielectric nanoparticles, the dielectric nanoparticles may be fabricated directly above the enhancement layer. FIG. 3e, FIG. 3f, FIG. 3g, and FIG. 3h illustrate example OLED stacks where the nanoparticles are fabricated directly above the enhancement layer. In the case that the stack includes separate enhancement layers and a second electrode, for example, as illustrated in FIG. 3g and FIG. 3h, the enhancement layer will be disposed over the second electrode and the nanoparticles will be fabricated directly above the enhancement layer. FIG. 3g illustrates the enhancement layer disposed directly on top of the second electrode, whereas FIG. 3h illustrates a dielectric spacer layer 350 located between the second electrode and the enhancement layer. Specifically, FIG. 3h illustrates the dielectric spacer layer disposed above the second electrode and disposed below the enhancement layer.

When utilizing metal nanoparticles, a dielectric spacer layer 350 may be deposited between the enhancement layer and the metal nanoparticles, for example, as illustrated in FIG. 3a, FIG. 3c, and FIG. 3d. In other words, the outcoupling layer may include a dielectric spacer layer. The dielectric spacer layer may be of a thickness less than 20 nm, less than 40 nm, and/or less than 60 nm. The refractive index of the dielectric spacer layer may be less than 1.4, less than 1.6, less than 1.8, and/or less than 2. The dielectric spacer layer may be deposited above the enhancement layer in the region inside and in between the shaped structures. In other words, the dielectric spacer layer may be located both inside the shaped structures and outside the shaped structures. The metal nanoparticles may then be deposited on the dielectric spacer layer within the shaped structures. In other words, the metal nanoparticles may be disposed in direct contact with a top of the dielectric layer. In the case that the stack includes separate enhancement layer and a second electrode 360, for example, as illustrated in FIG. 3d, the enhancement layer may be deposited above the second electrode. While not illustrated in the figures, the stack could also include another dielectric spacer layer located or disposed between the enhancement layer and the second electrode.

When an electrode layer that is separate from the enhancement layer is utilized, for example, as illustrated in FIG. 3d, FIG. 3g, and FIG. 3h, the electrode may be deposited above the organic (emissive) layer and the enhancement layer may be deposited on the top surface of the electrode. Alternatively, the electrode may be deposited above the enhancement layer. In other words, the enhancement layer could be located between two electrodes, with one of the electrodes being a thin layer of metallic or non-metallic material that is deposited above the enhancement layer. The shaped structures and nanoparticles may then be deposited above the second electrode. A dielectric spacer layer may be deposited between the second electrode and the nanoparticle layer. The thickness of the dielectric spacer may be less than 50 nm, more preferably less than 20 nm. In some embodiments, the shaped structures and nanoparticles may be deposited directly above the second electrode.

Regardless of the location, the electrode may have a thickness of less than 60 nm. The electrode may be made of an optically transparent material. The optically transparent material may include indium tin oxide, fluorine doped tin oxide, indium doped zinc oxide, aluminum zinc oxide, indium-doped cadmium oxide, barium stannate, carbon nanotubes, graphene, multilayer graphene, single layer graphene, graphene oxide, metallic nanoparticles, nanowire impregnated materials, polyacetylene, polypyrrole, polyindole, polyaniline, Poly(p-phenylene vinylene), poly(3-alkylthiophenes), (poly(3,4-ethylenedioxythiophene)), strontium niobium oxide, and/or the like. The electrode may, alternatively, be a metal material. The distance between the top of the emissive material layer and the bottom of the electrode may be less than 10 nm, less than 20 nm, or less than 30 nm. The electrode may also be deposited directly on the top surface of the EML layer.

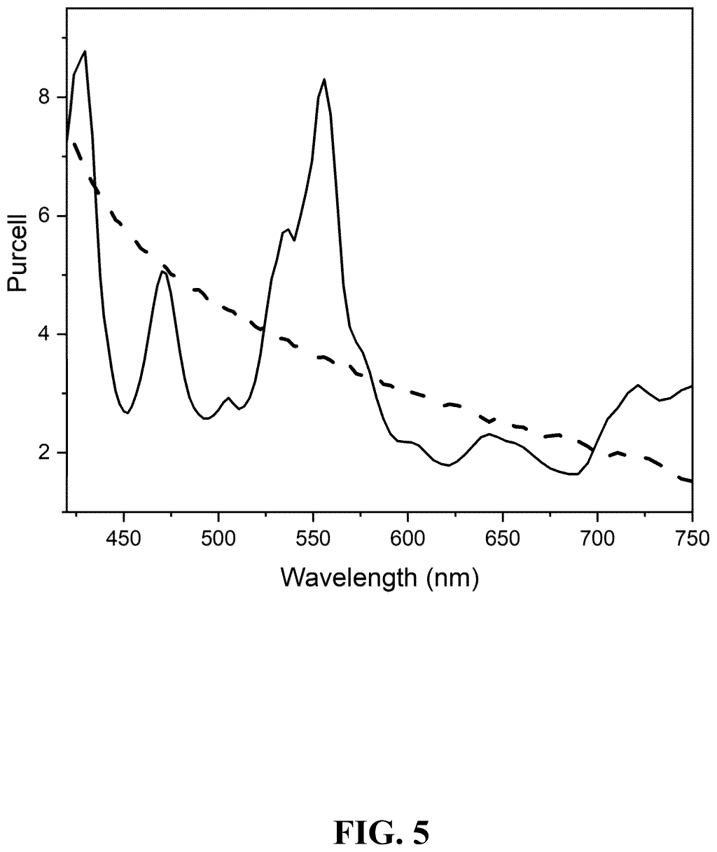

FIG. 5 shows the Purcell variation for a plasmonic OLED device utilizing shaped structures and nanoparticles for light outcoupling estimated based on numerical simulations. This indicates considerable Purcell enhancement compared to a plasmonic OLED device with a random nanoparticle outcoupling layer. The dashed line represents the simulated Purcell values for a typical plasmonic OLED device. The simulations were performed using a finite difference time domain (FDTD) method using a commercially available FDTD solution. Different layers of the OLED devices were rendered into a computational volume of 7 μm×7 μm×1.5 μm by their refractive index values and were enclosed within the perfectly matched layers (PML) in all direction to match the open boundary conditions. A single dipole emitter in vertical or horizontal orientation with broad emissions spectrum covering the entire visible region (420-750 nm), placed 20 nm away from a 30 nm thick silver electrode acts as the emissive layer. A 75 nm thick non-absorbing dielectric layer with a refractive index of 1.7 was used to model the host medium.

The metallic and dielectric structures of the outcoupling layer with optimum dimensions and ordering were placed above the cathode. Experimentally determined refractive index values were used to model the silver cathode and the refractive values by Johnson and Christy were used for modeling metallic structures in the outcoupling layer. The computational volume was discretized with a non-uniform index adjusted rectangular mesh with a resolution of 34 mesh cells per wavelength. Additionally, a mesh override region with 2 nm resolution was applied in the simulation region encompassing the silver cathode and metallic structures to minimize the computational error. The Purcell enhancement was estimated by calculating the power emitter by the dipole using a box of monitors surrounding the emitter normalized to the free space emission power. The light emissions in the far field were recorded using a frequency-domain field and power monitor placed 500 nm above the outcoupling layer, which were used to estimate EQE of the device. The monitor also records the electric and magnetic field components

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A device, the device comprising:
a substrate;
a first electrode;
an emissive layer disposed over the first electrode;
an enhancement layer disposed over the emissive layer; and
an outcoupling layer disposed over the enhancement layer, wherein the outcoupling layer comprises a plurality of shaped structures, wherein each of the shaped structures comprises nanoparticles.

2. The device of claim 1, wherein the nanoparticles are located in an interior of the shaped structure and wherein a shape of the shaped structures is selected to enhance a Purcell factor of the device.

3. The device of claim 1, wherein the enhancement layer comprises a second electrode.

4. The device of claim 1, wherein the nanoparticles are in direct contact with the enhancement layer.

5. The device of claim 1, further comprising a dielectric layer disposed between the enhancement layer and the outcoupling layer.

6-7. (canceled)

8. The device of claim 1, wherein the shaped structures are made from a material selected from the group consisting of: metal material and dielectric material.

9. The device of claim 1, wherein the shaped structures are distributed within the outcoupling layer in a periodic positional order.

10. The device of claim 1, wherein the shaped structures are distributed within the outcoupling layer in a random positional order.

11. The device of claim 1, wherein the nanoparticles are distributed within the shaped structures in a periodic order.

12. (canceled)

13. The device of claim 1, wherein the nanoparticles are distributed within the shaped structures in a random order.

14-18. (canceled)

19. The device of claim 1, wherein the nanoparticles have a shape, wherein the shape of the nanoparticles is selected from the group consisting of: cubes, hemispheres, cylinders, square pyramids, rectangular pyramids, triangular pyramids, and cuboids.

20. (canceled)

21. The device of claim 1, wherein at least a plurality of the nanoparticles comprises dielectric nanoparticles made of a dielectric material, wherein the dielectric material has a refractive index of at least 1.8.

22-38. (canceled)

39. The device of claim 1, wherein the shape comprises a ring shape.

40. The device of claim 39, wherein an inner diameter of the ring shape is less than 550 nm; and
wherein a selected inner diameter enhances a Purcell factor of the device for a range of wavelength values.

41. The device of claim 39, wherein a Purcell factor of the device is enhanced for a range of wavelength values corresponding to red optical emissions; and
wherein the inner diameter of at least a plurality of the ring shapes is 500 nm±50 nm.

42. The device of claim 39, wherein a Purcell factor of the device is enhanced for a range of wavelength values corresponding to green optical emissions; and
wherein the inner diameter of at least a plurality of the ring shapes is 420 nm±50 nm.

43. The device of claim 39, wherein a Purcell factor of the device is enhanced for a range of wavelength values corresponding to blue optical emissions; and
wherein the inner diameter of at least a plurality of the ring shapes is 350 nm±50 nm.

44-54. (canceled)

55. The device of claim 1, wherein the emissive layer comprises one or more emissive materials selected from the group consisting of: a phosphorescent emitter, a phosphor-sensitized fluorescent emitter, a thermally-activated delayed fluorescence (TADF) emitter, a phosphor-sensitized TADF, and a fluorescent emitter.

56. The device of claim 1, wherein a bottom edge of the nanoparticles is located on a plane different than a plane of a bottom edge of the shaped structures.

57. The device of claim 1, wherein a bottom edge of the nanoparticles is located on a same plane as a bottom edge of the shaped structures.

58-59. (canceled)
